(19) United States
(12) Patent Application Publication
(10) Pub. No.: US 2012/0255162 A1
(43) Pub. Date: Oct. 11, 2012

(54) TEMPERATURE-SENSITIVE PELLET TYPE THERMAL FUSE

(75) Inventor: Yukio Tamura, Chuo-ku (JP)

(73) Assignee: The Hosho Corporation, Tokyo (JP)

(21) Appl. No.: 12/866,066

(22) PCT Filed: Jun. 23, 2010
(86) PCT No.: PCT/JP10/04188

§ 371 Date: Jun. 26, 2012

(30) Foreign Application Priority Data
Nov. 30, 2009 (JP) 2009 271276

(51) Int. Cl. H01H 85/055; H05K 13/04; H01H 69/02

(52) U.S. Cl. 29/623; 337/228; 29/592.1

(57) ABSTRACT

The present invention provides a temperature-sensitive pellet type thermal fuse, a manufacturing method of the temperature-sensitive pellet type thermal fuse and a mounting method of the temperature-sensitive pellet type thermal fuse which, when the fuse is mounted on a temperature control target object having a planar portion, can ensure a high heat response speed, can decrease the difference in a heat response time for every product, can ensure high operational reliability, reduces the number of parts, and can reduce a manufacturing cost. A temperature-sensitive pellet type thermal fuse includes: an elongated case which has a hollow portion in the inside thereof; a first lead line which is arranged on one longitudinal end portion side of the elongated case along the longitudinal direction; a second lead line which is arranged on the other longitudinal end portion side of the elongated case along the longitudinal direction; and a movable contact which is arranged in the hollow portion and is brought into contact with the second lead line which is always biased in the move-away direction by way of a molten pellet arranged in contact with the first lead line, the movable contact being movable away from the second lead line due to a biasing force when a temperature of a temperature control target object arrives at a predetermined temperature or more and the molten pellet is melted thus cutting off a power source circuit, wherein the elongated case includes a planar portion which is brought into face contact with a planar portion of the temperature control target object.

### TECHNICAL FIELD

The present invention relates to improvements of a temperature-sensitive pellet type thermal fuse which detects a temperature of a temperature control target object, a manufacturing method of the temperature-sensitive pellet type thermal fuse, and a mounting method of the thermal fuse.

### BACKGROUND ART

An electric product of nowadays is constituted of various kinds of parts and, particularly recently, the structure of the electric product is becoming more complicated.

Among these parts, there is a temperature control target object having a heating element which generates heat during an operation due to electric resistance which each constitutional material has, a heater function or the like.

Due to a storage of heat in the temperature control target object, when a temperature of a part is excessively elevated, an erroneous operation of the part is induced resulting in the occurrence of ignition. In view of the above, to prevent the occurrence of ignition of the temperature control target object by speedily detecting abnormal heating and by taking a protective measure of cutting off a power source circuit, a thermal fuse is mounted on the temperature control target object.

As one typical mode of the above-mentioned thermal fuse, there has been known a temperature-sensitive pellet type thermal fuse which includes: a cylindrical case which has a hollow portion in the inside thereof; a first lead line which is arranged on one longitudinal end portion side of the cylindrical case along the longitudinal direction; a second lead line which is arranged on the other longitudinal end portion side of the cylindrical case along the longitudinal direction; and a movable contact which is arranged in the hollow portion and is brought into contact with the second lead line which is always biased in the move-away direction by way of a molten pellet arranged in contact with the first lead line, wherein when a temperature of a temperature control target object arrives at a predetermined temperature or more, the molten pellet is melted, and the movable contact is separated from the second lead line due to the biasing force thus cutting off a power source circuit

FIG. 9 is a perspective view showing the overall profile of a conventional temperature-sensitive pellet type thermal fuse 50.

As shown in FIG. 9, the conventional temperature-sensitive pellet type thermal fuse 50 includes a cylindrical case 51 which is formed into an approximately cylindrical bottomed shape as a whole, a first lead line 52 which is arranged on one end portion 51a side of the cylindrical case 51 along the longitudinal direction, and a second lead line 53 which is arranged on the other end portion 51b side of the circular cylindrical case 51 along the longitudinal direction.

Further, FIG. 10 shows the conventional temperature-sensitive pellet type thermal fuse 50, wherein FIG. 10(a)-1 is a front view of the temperature-sensitive pellet type thermal fuse 50 in a conductive state, FIG. 10(a)-2 is a longitudinal cross-sectional view of the temperature-sensitive pellet type thermal fuse 50 in a conducive state, FIG. 10(a)-3 is a rear view of the temperature-sensitive pellet type thermal fuse 50 in a conductive state, FIG. 10(b)-1 is a front view of the temperature-sensitive pellet type thermal fuse 50 in a cut-off state, FIG. 10(b)-2 is a longitudinal cross-sectional view of the temperature-sensitive pellet type thermal fuse 50 in a cut-off state, and FIG. 10(b)-3 is a rear view of the temperature-sensitive pellet type thermal fuse 50 in a cut-off state.

As shown in FIG. 10(a)-2, the above-mentioned circular cylindrical case 51 has the hollow portion 54 in the inside thereof.

Further, a caulking hole portion 51c for fixing a rear end portion 52a of the above-mentioned first lead line 52 is formed in one end portion 51a of the circular cylindrical case 51.

Further, in the hollow portion 54, a solid circular columnar molten pellet 55 which is melted at a predetermined temperature, a first pushing plate 63 which has one surface portion thereof brought into contact with the molten pellet 55, a first coil spring 62 which has one end portion thereof brought into contact with the other surface portion of the first pushing plate 63, a second pushing plate 61 which has one surface portion thereof brought into contact with the other end portion of the first coil spring 62, and a movable contact 56 which has one surface portion thereof brought into contact with the other surface portion of the second pushing plate 61 are arranged.

Further, a rear end portion 53a of the second lead line 53 is arranged at an approximately longitudinal center portion of the hollow portion 54 of the circular cylindrical case 51 in a state where the rear end portion 53a is brought into contact with the other surface portion of the movable contact 56.

Further, with respect to the second lead line 53, an outer peripheral portion of a portion 53b which is arranged inside the circular cylindrical case 51 is formed into a substantially circular cylindrical shape as a whole, and a ceramic-made bushing 57 which has projecting portions 57a, 57b on both longitudinal end portions thereof is arranged on the outer peripheral portion of the portion 53b.

Further, with respect to the circular cylindrical case 51, on an approximately longitudinally center portion of an inner peripheral surface portion 51d slightly closer to the other end portion 51b, the bushing fixing stepped portion 58 is formed, and an outer peripheral surface portion of the bushing 57 is fitted in the bushing fixing stepped portion 58.

Further, the bushing 57 is formed into a substantially circular cylindrical shape as a whole, and the bushing 57 includes the projecting portions 57a, 57b on both longitudinal end portions thereof. A proximal end portion of the projecting portion 57a is engaged with one end portion 58a of the bushing fixing stepped portion 58 and, at the same time, a peripheral portion of the projecting portion 57b is fixed to the bushing fixing stepped portion 58 by a the-other-end portion 58b of the bushing fixing stepped portion by caulking.

Further, to the other end portion 51b of the circular cylindrical case 51, a fitting member 59 which is made of an epoxy resin and is formed into a substantially frustoconical shape is provided. The second lead line 53 is arranged such that the second lead line 53 penetrates the bushing 57 and the fitting member 59 and projects in the longitudinal outward direction of the circular cylindrical case 51 from the other end portion 51b of the circular cylindrical case 51.

The movable contact 56 is formed of a metal-made disc having an outer peripheral portion thereof bent along the longitudinal direction of the circular cylindrical case 51, the movable contact 56 is arranged in a state where the movable contact 56 is brought into contact with the above-mentioned rear end portion 53a of the second lead line 53 and, at the same time, the outer peripheral portion of the movable contact 56 is brought into slide contact with the inner peripheral surface portion 51d of the circular cylindrical case 51 along the longitudinal direction of the circular cylindrical case 51.

Further, the movable contact 56 is biased by a second coil spring 60 in the direction that the movable contact 56 moves away from the rear end portion 53a of the second lead line 53.

Further, the second pushing plate 61 is arranged in a state where the second pushing plate 61 is brought into contact with the movable contact 56. Further, on a side of the second pushing plate 61 opposite to the movable contact 56 side, the first pushing plate 63 is arranged by way of the first coil spring 62. The first coil spring 62 biases the second pushing plate 61 and the first pushing plate 63 in the direction that the second pushing plate 61 and the first pushing plate 63 move away from each other at a steady temperature state.

In a case shown in FIG. 10(a), an electric current is held in a conductive state by a circuit which is constituted of the first lead line 52, the inner peripheral surface portion 51d of the circular cylindrical case 51, the movable contact 56, and the second lead line 53.

Further, FIG. 11 is a radially transverse cross-sectional view of the conventional temperature-sensitive pellet type thermal fuse in a state where the thermal fuse is mounted on a planar surface of a temperature control target object.

As shown in FIG. 11, when the temperature-sensitive pellet type thermal fuse 50 is mounted on a planar portion 65 of the temperature control target object 64 whose temperature is to be detected in a contact manner, the temperature-sensitive pellet type thermal fuse 50 is mounted by way of silicon-made heat conductive grease 66.

Along with the temperature elevation of the temperature control target object 64, heat is transferred to the circular cylindrical case 51 so that a temperature of the circular cylindrical case 51 is elevated. At a point of time that the temperature of the circular cylindrical case 51 exceeds a predetermined temperature, as shown in FIG. 10(b), the molten pellet 55 (not shown in FIG. 10(b)) is melted.

When the molten pellet 55 is melted, the second coil spring 60 and the first coil spring 62 extend. Due to a biasing force of the second coil spring 60, the movable contact 56 moves in the direction toward one end portion 51a of the circular cylindrical case 51 side and slides along the inner peripheral surface portion 51d of the circular cylindrical case 51 so that the movable contact 56 moves away from a rear end portion 53a of the second lead line 53.

Due to such an operation, a contact between the movable contact 56 and the rear end portion 53a of the second lead line 53 is released so that a power source circuit is cut off whereby the supply of electricity to the temperature control target object 64 is stopped thus preventing the temperature elevation.

However, as shown in FIG. 11, when the temperature control target object 64 which is an object on which the conventional temperature-sensitive pellet type thermal fuse 50 is mounted has a planar portion 65, a contact between the temperature control target object 64 and an outer peripheral surface portion 51e of the circular cylindrical case 51 of the temperature-sensitive pellet type thermal fuse 50 becomes a line contact along the longitudinal direction of the circular cylindrical case 51 and hence, a contact area becomes extremely small.

Further, heat absorbed from the temperature control object 64 is discharged to the outside from the outer peripheral surface portion 51e which is not in contact with the planar portion 65 to the outside and hence, the temperature elevation of the circular cylindrical case 51 becomes difficult whereby even when the temperature of the temperature control target object 64 is elevated, heat is not rapidly transferred to the molten pellet 55. Accordingly, there has been a drawback that a heat response speed from a point of time that the temperature of the temperature control target object 64 reaches a predetermined temperature to a point of time that the temperature-sensitive pellet type thermal fuse 50 is operated is delayed.

Further, since a contact state between the temperature control target object 64 and the temperature-sensitive pellet type thermal fuse 50 is a line contact, the heat conduction to the circular cylindrical case 51 is liable to become unstable thus giving rise to a case where melting of the temperature-sensitive pellet 55 occurs non-uniformly. Accordingly, the above-mentioned temperature-sensitive pellet type thermal fuse has a drawback that the fuse causes a defective cut-off of a power source circuit in addition to delaying of a heat response speed.

Accordingly, it is difficult for the conventional temperature-sensitive pellet type thermal fuse 50 provided with the cylindrical case to ensure the sufficient operational reliability.

To overcome the above-mentioned drawbacks, as shown in FIG. 12, there has been proposed a thermal fuse 70 in which a cylindrical through hole 73 having the approximately same diameter as a temperature-sensitive pellet type thermal fuse body 71 is formed in a solid heat absorbing fin 72 having an approximately elongated rectangular parallelepiped shape in the longitudinal direction, and the temperature-sensitive pellet type thermal fuse body 71 is inserted into and fixed to the through hole 73 (patent document 1).

In patent document 1, there is the description that the heat absorbing fin 72 is formed of a favorable heat conductive body and hence, heat is transferred to the temperature-sensitive pellet type thermal fuse body 71 more rapidly thus enhancing a heat response speed.

However, in patent document 1, as can be clearly understood also from FIG. 12, the thermosetting pellet type thermal fuse body 71 is inserted into and mounted in the inside of the cylindrical through hole 73 formed along the longitudinal direction of the heat absorbing fin 72 so that the temperature-sensitive pellet type thermal fuse body 71 and the heat absorbing fin 72 are formed as separate bodies. Accordingly, heat is not rapidly transferred in a boundary portion between the heat absorbing fin 72 and the temperature-sensitive pellet type thermal fuse body 71 thus delaying a heat response time.

Further, in the temperature-sensitive pellet type thermal fuse 70, the temperature-sensitive pellet type thermal fuse body 71 has a diameter smaller than a width of the solid heat absorbing fin 72 and hence, to allow the heat conduction to a portion inside a wall thickness (L) of the heat absorbing fin 72, it is necessary to allow heat to pass through the heat absorbing fin 72 and the temperature-sensitive pellet type thermal fuse body 71 whereby a heat response speed is further delayed.

Accordingly, with respect to the responsiveness of the thermal fuse 70 according to patent document 1, data which supports the responsiveness of the thermal fuse 70 is not disclosed and hence, the responsiveness of the thermal fuse 70 is extremely indefinite.

Further, in the temperature-sensitive pellet type thermal fuse 70, it is necessary to additionally mount the heat absorbing fin 72 on the temperature-sensitive pellet type thermal fuse body 71 and hence, the number of parts and machining man-hours are increased whereby a manufacturing cost is pushed up. Further, due to tolerance in machining accuracy, it is difficult to maintain a heat response time at a fixed value for every product. Further, it is also impossible to completely prevent a defective cut-off thus giving rise to a drawback that it is difficult for the temperature-sensitive pellet type thermal fuse 70 to ensure the high operational reliability.
Patent document 1: JP-A-11-306939

### DISCLOSURE OF THE INVENTION

### Problem that the Invention is to Solve

It is an object of the present invention to provide a temperature-sensitive pellet type thermal fuse, a manufacturing method of the temperature-sensitive pellet type thermal fuse and a mounting method of the temperature-sensitive pellet type thermal fuse which, when the fuse is mounted on a temperature control target object having a planar portion, can ensure a high heat response speed, decreases the difference in a heat response time for every product, can ensure high operational reliability, reduces the number of parts, and can reduce a manufacturing cost.

### Means for Solving the Problem

To overcome the above-mentioned drawbacks, a temperature-sensitive pellet type thermal fuse according to the invention called for in claim 1 includes: an elongated case which has a hollow portion in the inside thereof; a first lead line which is arranged on one longitudinal end portion side of the elongated case along the longitudinal direction; a second lead line which is arranged on the other longitudinal end portion side of the elongated case along the longitudinal direction; and a movable contact which is arranged in the hollow portion and is brought into contact with the second lead line which is always biased in the move-away direction by way of a molten pellet arranged in contact with the first lead line, the movable contact being movable away from the second lead line due to a biasing force when a temperature of a temperature control target object arrives at a predetermined temperature or more and the molten pellet is melted thus cutting off a power source circuit, wherein the elongated case includes a planar portion which is brought into face contact with a planar portion of the temperature control target object.

Accordingly, when the temperature-sensitive pellet type thermal fuse is mounted on the temperature control target object having the planar portion, the planar portion of the temperature control target object and the planar portion of the temperature-sensitive pellet type thermal fuse are brought into face contact with each other so that a contact area between these planar portions can be increased compared to a case where a conventional cylindrical temperature-sensitive pellet type thermal fuse is in brought into line contact with the planar portion of the temperature control target object whereby the fuse can ensure a large heat value thus ensuring a rapid heat response speed.

Further, the temperature-sensitive pellet type thermal fuse according to the invention called for in claim 2 is that the elongated case is formed into a regular multi-sided cylinder as a whole.

Accordingly, the elongated case has a plurality of planar portions which can be brought into contact with the planar portion of the temperature control target object.

Further, the temperature-sensitive pellet type thermal fuse according to the invention called for in claim 3 is that the elongated case is formed into a regular four-sided cylinder as a whole.

Accordingly, the elongated case has four planar portions which can be brought into contact with the planar portion of the temperature control target object.

Further, the temperature-sensitive pellet type thermal fuse according to the invention called for in claim 4 is that on the other longitudinal end portion of an inner peripheral surface portion of the elongated case, a bushing fixing stepped portion is formed over a predetermined length.

Accordingly, in the bushing fixing stepped portion, it is possible to surely fix the bushing.

Further, the temperature-sensitive pellet type thermal fuse according to the invention called for in claim 5 is that in the elongated case, a wall thickness of the planar portion which is brought into contact with the temperature control target object is set to 0.4 mm or less, and a wall thickness of the bushing fixing stepped portion is set to 0.2 mm.

Accordingly, the thickness of the elongated case becomes further small and hence, the heat conduction from the temperature control target object which constitutes an object to be mounted to the temperature-sensitive pellet sealed in the inside of the elongated case is rapidly carried out and, at the same time, a wall thickness of the bushing fixing stepped portion is made further small and hence, the bushing can be easily fixed by caulking.

Further, the temperature-sensitive pellet type thermal fuse according to the invention called for in claim 6 is that a surface roughness of the planar portion of the elongated case is set such that the difference between a concave portion and a convex portion of the uneveness is set to 6.3 μm or less.

Accordingly, the surface portion of the elongated case is formed extremely smoothly and hence, it is possible to bring the surface portion of the elongated case into close contact with the planar portion of the temperature control target object.

Further, the temperature-sensitive pellet type thermal fuse according to the invention called for in claim 7 is that an outer surface portion of the elongated case is covered with a silver plating layer.

Silver possesses high heat conductivity next to gold and hence, the heat conduction to the elongated case is facilitated.

Further, the temperature-sensitive pellet type thermal fuse according to the invention called for in claim 8 is that the elongated case is made of brass.

Heat conductivity of copper contained in brass is high and hence, the heat conduction toward the elongated case is facilitated.

A manufacturing method of the elongated case of the temperature-sensitive pellet type thermal fuse according to the invention called for in claim 9 includes the steps of: forming a metal base member having a four-sided cylindrical profile as a whole and having a circular cylindrical hollow portion which includes an opening portion on both end portions thereof along a longitudinal direction of the four-sided cylinder as an integral body by drawing using a mold; forming a four-sided cylindrical case base member having the opening portion on both longitudinal end portions thereof by cutting the metal base member into a predetermined size; forming a pair of short circular cylindrical portions which projects outward in the longitudinal direction and has the same inner diameter as the circular cylindrical hollow portion at both longitudinal end portions of the four-sided cylindrical case base member by cutting; and forming a caulking hole portion by gradually narrowing a diameter of an opening portion of one of the pair of short circular cylindrical portions by drawing and forging.

Accordingly, it is possible to collectively form the metal base member having the four-sided cylindrical profile and the circular cylindrical hollow portion in the inside thereof by drawing.

A manufacturing method of the elongated case of the temperature-sensitive pellet type thermal fuse according to the invention called for in claim 10 includes the steps of: forming a four-sided cylindrical case base member by cutting a metal base member formed in a four-sided cylindrical shape by drawing into a predetermined length: forming a circular cylindrical hollow portion in the four-sided cylindrical case base member by cutting; forming a short circular cylindrical portion which projects outward in the longitudinal direction at one end portion of the four-sided cylindrical case base member by cutting; and forming a caulking hole portion at the other end portion of the four-sided cylindrical case base member by cutting.

Accordingly, it is possible to form the elongated case having the four-sided cylindrical profile and the circular cylindrical hollow portion in the inside thereof using a single member.

Further, the manufacturing method of the elongated case of the temperature-sensitive pellet type thermal fuse according to the invention called for in claim 11 further includes a step of forming a bushing fixing stepped portion over a predetermined length on an inner peripheral surface portion of the hollow portion on the other longitudinal end portion side by cutting.

Accordingly, it is possible to form the elongated case having the bushing fixing stepped portion on the inner peripheral portion of the hollow portion on the other longitudinal end portion side.

Further, amounting method of the temperature-sensitive pellet type thermal fuse according to the invention called for in claim 12 includes the steps of: bringing a planar portion of the temperature control target object and a planar portion of the elongated case into contact with each other; arranging a biasing member which biases the elongated case in the direction which brings the elongated case into close contact with the temperature control target object from a side opposite to a contact surface portion of the elongated case; and fixing the elongated case to the temperature control target object in a close contact state by a biasing force of the biasing member.

Accordingly, the planar portion of the elongated case and the planar portion of the temperature control target object are fixed to each other in a state where these planar portions are brought into a close contact state by the biasing force of the biasing member.

Further, the mounting method of the temperature-sensitive pellet type thermal fuse according to the invention called for in claim 13 is characterized in that the biasing member is a spring member.

Accordingly, the planar portion of the elongated case and the planar portion of the temperature control target object are fixed to each other in a state where these planar portion are brought into a close contact state by the biasing force of the spring member.

Further, the mounting method of the temperature-sensitive pellet type thermal fuse according to the invention called for in claim 14 is characterized in that the temperature control target object is a heating element which is mounted on a fixing unit of a copying machine printer.

### ADVANTAGE OF THE INVENTION

According to the invention called for in claim 1, the elongated case has the planar portion which is brought into face contact with the planar portion of the temperature control target object. Accordingly, when the elongated case is mounted on the temperature control target object having the planar portion, different from the conventional case where the elongated case and the temperature control target object are brought into contact with each other by line contact, a large contact surface is obtained thus allowing the fuse to ensure a high heat response speed by high-speed heat conduction.

Further, according to the inventions called for in claims 2 and 3, the elongated case is formed into the regular multi-sided cylinder or the regular four-sided cylinder. Accordingly, in addition to the advantage acquired by the invention described in claim 1, when an arbitrary side surface portion of the elongated case is mounted on the planar portion of the temperature control target object, the elongated case has a plurality of planar portions which are brought into contact with the temperature control target object and hence, even when the temperature control target object has a plurality of planar portions, the elongated case is effectively brought into face contact with the temperature control target object whereby it is possible to ensure the versatility of the arrangement of the fuse.

Further, any one of surfaces of the elongated case can be arranged to be brought into contact with the planar portion of the temperature control target object and hence, the planar portion of the elongated case for contact is not limited thus further enhancing the versatility of the arrangement.

Further, according to the invention called for in claim 4, on the other longitudinal end portion of the elongated case, the bushing fixing stepped portion is formed in an over a predetermined length. Accordingly, it is possible to position the second lead line and a bushing arranged on a peripheral portion of the second lead line on the other longitudinal end portion of the elongated case with high accuracy, and it is also possible to fix the second lead line and the bushing in a more stable manner.

Further, according to the invention called for in claim 5, the wall thickness of the planar portion of the elongated case which is brought into contact with the temperature control target object is set to 0.4 mm or less, and the wall thickness of the bushing fixing stepped portion is set to 0.2 mm. Accordingly, the wall thickness of the portion of the elongated case which is brought into contact with the planar portion of the temperature control target object is small so that it is also possible to shorten a heat response time in addition to the advantage acquired by the invention described in claim 1.

Further, according to the invention called for in claim 6, the surface roughness of the planar portion of the elongated case is set such that the difference between the concave portion and the convex portion of the uneveness is set to 6.3 μm or less. Accordingly, it is possible to bring the planar portion of the elongated case into close contact with the planar portion of the temperature control target object and hence, the elongated case can ensure a large heat receiving area whereby it is possible to further shorten the heat response time due to a large heat conduction effect.

Further, according to the invention called for in claim 7, the outer surface portion of the elongated case is covered with the silver plating layer. Accordingly, a heat conduction effect attributed to the high heat conductivity of silver is large so that it is possible to further shorten the heat response time.

Further, according to the invention called for in claim 8, the elongated case is made of brass. Accordingly, a heat conduction effect attributed to high heat conductivity of copper contained in brass is large so that it is possible to further shorten the heat response time.

Further, according to the invention called for in claim 9, the manufacturing method of the elongated case of the temperature-sensitive pellet type thermal fuse includes the steps of: forming a metal base member having a four-sided cylindrical profile as a whole and having a circular cylindrical hollow portion which includes an opening portion on both end portions thereof along a longitudinal direction of the four-sided cylinder as an integral body by drawing using a mold; forming a four-sided cylindrical case base member having an opening portion on both longitudinal end portions thereof by cutting the metal base member into a predetermined size; forming a pair of short circular cylindrical portions which projects outward in the longitudinal direction and has the same inner diameter as the circular cylindrical hollow portion at both longitudinal end portions of the four-sided cylindrical case base member by cutting; and forming a caulking hole portion by gradually narrowing a diameter of an opening portion of one of the pair of short circular cylindrical portions by drawing and forging. Due to such steps, it is possible to decrease the number of cutting steps which require large machining man-hours.

Accordingly, it is possible to provide the temperature-sensitive pellet type thermal fuse which exhibits the small difference in heat response time for every product, can ensure the high operational reliability, and has the small number of parts thus reducing a manufacturing cost.

Further, according to the invention called for in claim 10, the manufacturing method of the elongated case of the temperature-sensitive pellet type thermal fuse includes the steps of: forming a four-sided cylindrical case base member by cutting a metal base member formed in a four-sided cylindrical shape by drawing into a predetermined length; forming a circular cylindrical hollow portion in the four-sided cylindrical case base member by cutting; forming a short circular cylindrical portion which projects outward in the longitudinal direction at one end portion of the four-sided cylindrical case base member by cutting; and forming a caulking hole portion at the other end portion of the four-sided cylindrical case base member by cutting. Accordingly, the elongated case having the four-sided cylindrical shape can be formed using a single member and hence, compared to the thermal fuse described in patent document 1 which has the same appearance, it is possible to facilitate the machining of the elongated case which possesses the excellent heat responsiveness and, it is also possible to decrease the number of parts thus reducing a manufacturing cost.

Further, according to the invention called for in claim 11, the manufacturing method of the elongated case of the temperature-sensitive pellet type thermal fuse further includes the step of forming a bushing fixing stepped portion over a predetermined length on an inner peripheral surface portion of the hollow portion on the other longitudinal end portion side by cutting. Due to such a step, it is possible to provide the elongated case which can further facilitate a caulking operation at the time of fixing the bushing.

Accordingly, it is possible to provide the temperature-sensitive pellet type thermal fuse which exhibits the small difference in heat response time for every product, can ensure the high operational reliability, and has the small number of parts thus reducing a manufacturing cost.

Further, according to the inventions called for in claims 12 to 14, the temperature-sensitive pellet type thermal fuse and the temperature control target object are brought into close contact with each other and are fixed to each other due to the biasing force of the biasing member. Accordingly, heat is efficiently transferred to the temperature-sensitive pellet type thermal fuse from the temperature control target object and hence, it is possible to further shorten the heat response time.

Further, it is no more necessary to use expensive silicon heat conductive grease which has been used conventionally and the elongated case has the planar portion so that it is possible to push the elongated case to the temperature control target object easily and without displacement by means of the biasing member whereby it is possible to decrease the number of man-hours for a mounting operation thus largely reducing a cost.

### BRIEF EXPLANATION OF THE DRAWINGS

FIG. 1 is a view showing one embodiment of the present invention, wherein FIG. 1(a) is a front view of a temperature-sensitive pellet type thermal fuse according to the embodiment, FIG. 1(b) is a whole side view of the temperature-sensitive pellet type thermal fuse, and FIG. 1(c) is a rear view of the temperature-sensitive pellet type thermal fuse.

FIG. 2 is a view showing one embodiment of the present invention, wherein FIG. 2(a)-1 is a front view of the temperature-sensitive pellet type thermal fuse of the embodiment in a conductive state, FIG. 2(a)-2 is a longitudinal cross-sectional view of the temperature-sensitive pellet type thermal fuse, FIG. 2(a)-3 is a rear view of the temperature-sensitive pellet type thermal fuse, FIG. 2(b)-1 is a front view showing the temperature-sensitive pellet type thermal fuse in a cut-off state, FIG. 2(b)-2 is a longitudinal cross-sectional view of the temperature-sensitive pellet type thermal fuse, and FIG. 2(b)-3 is a rear view of the temperature-sensitive pellet type thermal fuse.

FIG. 3 is a view showing one embodiment of the present invention, wherein FIG. 3(a) is a front view of an elongated case of the temperature-sensitive pellet type thermal fuse according to the embodiment, and FIG. 3(b) is a longitudinal cross-sectional view of the elongated case.

FIG. 4 is a view showing one embodiment of the present invention and showing a state where a temperature-sensitive pellet type thermal fuse according to the embodiment is mounted on a rear planar surface of a heating element used as a fixing unit of a copying machine printer which is a temperature control target object, wherein FIG. 4(a) is a cross-sectional view of the fixing unit including a mounting portion, and FIG. 4(b) is a perspective view showing the whole mounting configuration of the temperature-sensitive pellet type thermal fuse.

FIG. 5 is a view showing a change in shape of the elongated case of the temperature-sensitive pellet type thermal fuse according to the present invention in respective steps of one embodiment of a manufacturing method of the elongated case, wherein FIG. 5(a)-1 is a front view of the elongated case after a first step, FIG. 5(a)-2 is a longitudinal cross-sectional view of the elongated case, FIG. 5(a)-3 is a rear view of the elongated case, FIG. 5(b) is a perspective view of the elongated case after the first step, FIG. 5(c)-1 is a front view of the elongated case after a second step, FIG. 5(c)-2 is a longitudinal cross-sectional view of the elongated case, FIG. 5(c)-3 is a rear view of the elongated case, FIG. 5(d) is a perspective view of the elongated case after the second step, FIG. 5(e)-1 is a front view of the elongated case after a third step, FIG. 5(e)-2 is a longitudinal cross-sectional view of the elongated case, FIG. 5(e)-3 is a rear view of the elongated case, FIG. 5(f)-1 is a front view of the elongated case after the fourth step, FIG. 5(f)-2 is a longitudinal cross-sectional view of the elongated case after the fourth step, and FIG. 5(f)-3 is a rear view of the elongated case.

FIG. 6 is a view showing a change in shape of an elongated case of a temperature-sensitive pellet type thermal fuse according to the present invention in respective steps of a second embodiment of a manufacturing method of the elongated case, wherein FIG. 6(a)-1 is a front view of the elongated case after a first step, FIG. 6(a)-2 is a side view of the elongated case, FIG. 6(a)-3 is a rear view of the elongated case, FIG. 6(b) is a perspective view of the elongated case after the first step, FIG. 6(c)-1 is a front view of the elongated case after a second step, FIG. 6(c)-2 is a longitudinal cross-sectional view of the elongated case, FIG. 6(c)-3 is a rear view of the elongated case, and FIG. 6(d) is a perspective view of the elongated case after the second step.

FIG. 7 is a view showing another embodiment of the present invention, wherein FIG. 7(a) is a front view of a temperature-sensitive pellet type thermal fuse which uses the elongated case manufactured by the manufacturing method according to the second embodiment, FIG. 7(b) is an overall side view of the temperature-sensitive pellet type thermal fuse, and FIG. 7(c) is a rear view of the temperature-sensitive pellet type thermal fuse.

FIG. 8 is a view showing another embodiment of the present invention, wherein FIG. 8(a)-1 is a front view of a temperature-sensitive pellet type thermal fuse which uses an elongated case manufactured by the manufacturing method according to the second embodiment in a conductive state, FIG. 8(a)-2 is a longitudinal cross-sectional view of the temperature-sensitive pellet type thermal fuse, FIG. 8(a)-3 is a rear view of the temperature-sensitive pellet type thermal fuse, FIG. 8(b)-1 is a front view showing the temperature-sensitive pellet type thermal fuse in a cut-off state, FIG. 8(b)-2 is a longitudinal cross-sectional view of the temperature-sensitive pellet type thermal fuse, and FIG. 8(b)-3 is a rear view of the temperature-sensitive pellet type thermal fuse.

FIG. 9 is a perspective view of a conventional temperature-sensitive pellet type thermal fuse.

FIG. 10 is a view showing the conventional temperature-sensitive pellet type thermal fuse, wherein FIG. 10(a)-1 is a front view of the temperature-sensitive pellet type thermal fuse in a conductive state, FIG. 10(a)-2 is a longitudinal-cross-sectional view of the temperature-sensitive pellet type thermal fuse, FIG. 1(a)-3 is a rear view of the temperature-sensitive pellet type thermal fuse, FIG. 10(b)-1 is a front view of the temperature-sensitive pellet type thermal fuse in a cut-off state, FIG. 10(b)-2 is a longitudinal cross-sectional view of the temperature-sensitive pellet type thermal fuse, and FIG. 10(b)-3 is a rear view of the temperature-sensitive pellet type thermal fuse.

FIG. 11 is a radially transverse cross-sectional view of the conventional temperature-sensitive pellet type thermal fuse in a state where the thermal fuse is mounted on a planar surface of a temperature control target object.

FIG. 12 is a perspective view of another conventional temperature-sensitive pellet type thermal fuse.

FIG. 13 is a graph showing a result of a responsiveness test of the temperature-sensitive pellet type thermal fuse according to the embodiment 1, a responsiveness test of a conventional temperature-sensitive pellet type thermal fuse, and a responsiveness test of a thermal fuse in a mode disclosed in patent document 1.

### BEST MODE FOR CARRYING OUT THE INVENTION

A mode for carrying out the present invention is explained in conjunction with drawings by taking a case where a temperature control target object is a heating portion of a fixing unit of a copying machine printer as an example.

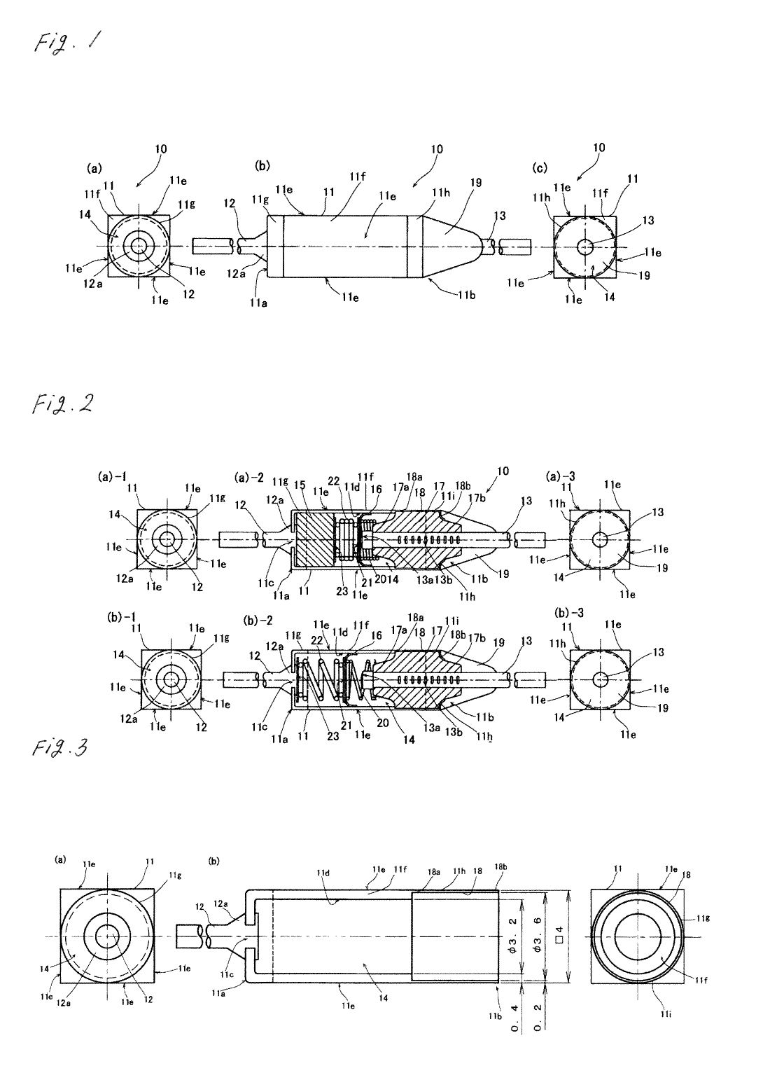

As shown in FIG. 1(a), a temperature-sensitive pellet type thermal fuse 10 according to this embodiment includes a four-sided cylindrical case 11 made of brass which has a hollow portion 14 therein. As shown in FIG. 1(b), the temperature-sensitive pellet type thermal fuse 10 includes a first lead line 12 which is arranged on one longitudinal end portion 11a side of the four-sided cylindrical case 11 along the longitudinal direction, and a second lead line 13 which is arranged on the other longitudinal end portion 11b side of the four-sided cylindrical case 11 along the longitudinal direction. As shown in FIG. 2(a)-2, temperature-sensitive pellet type thermal fuse 10 includes a movable contact 16 which is arranged in the hollow portion 14 and is brought into contact with the second lead line 13 which is always biased in the move-away direction by way of a molten pellet 15 arranged in contact with the above-mentioned first lead line 12. As shown in FIG. 4-(b), the above-mentioned four-sided cylindrical case 11 is formed into a square cylindrical shape as a whole, and has a planar portion 11e which can be brought into face contact with a rear planar portion 25 of a plate-shaped heater portion 24 of a fixing unit of a copying machine printer which is a temperature control target object.

Further, as shown in FIG. 2(a)-2, on the other longitudinal end portion 11b of an inner peripheral surface portion 11d of the four-sided cylindrical case 11, a bushing fixing stepped portion 18 is formed over a predetermined length.

Further, in the four-sided cylindrical case 11, a wall thickness of the planar portion 11e which is brought into contact with the temperature control target object is set to 0.4 mm or less and, at the same time, a wall thickness of the above-mentioned bushing fixing stepped portion 18 is set to 0.2 mm.

Further, the surface roughness of the planar portion 11e of the above-mentioned four-sided cylindrical case 11 is set such that the difference between a concave portion and a convex portion of the uneveness is set to 6.3 μm or less. Further, an outer surface portion of the four-sided cylindrical case 11 is covered with a silver plating layer.

### Embodiment 1

Hereinafter, the constitution of this embodiment is explained in detail in conjunction with drawings.

FIG. 1 shows a temperature-sensitive pellet type thermal fuse 10 according to this embodiment, wherein FIG. 1(a) is a front view of the temperature-sensitive pellet type thermal fuse 10, FIG. 1(b) is a whole side view of the temperature-sensitive pellet type thermal fuse 10, and FIG. 1(c) is a rear view of the temperature-sensitive pellet type thermal fuse 10.

As shown in FIG. 1(a) to FIG. 1(c), the temperature-sensitive pellet type thermal fuse 10 according to this embodiment includes a four-sided cylindrical case 11 which is formed into a substantially regular four-sided cylinder as a whole, wherein the case 11 has a longitudinal length of 8 mm. The four-sided cylindrical case 11 is constituted of a case body portion 11f, the above-mentioned case body portion 11f, and cylindrical projecting portions 11g, 11h which are formed on both longitudinal end portions of the case body portion 11f in a projecting manner.

Further, the temperature-sensitive pellet type thermal fuse 10 includes the first lead line 12 which is arranged on one longitudinal end portion 11a side of the four-sided cylindrical case 11 along the longitudinal direction and the second lead line 13 which is arranged on the other longitudinal end portion side of the four-sided cylindrical case 11 along the longitudinal direction.

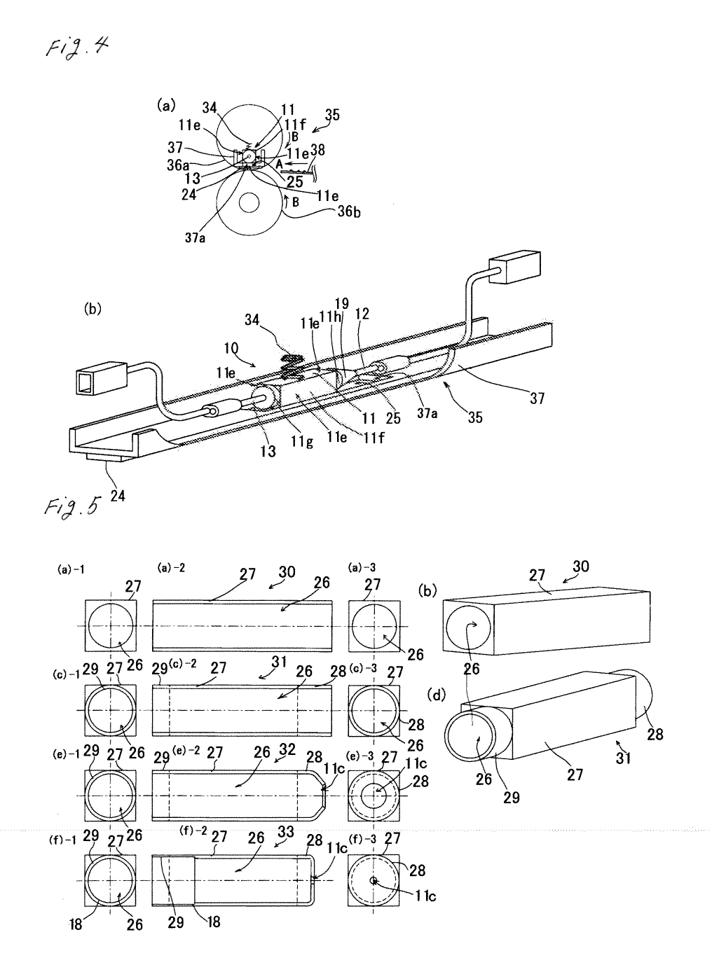

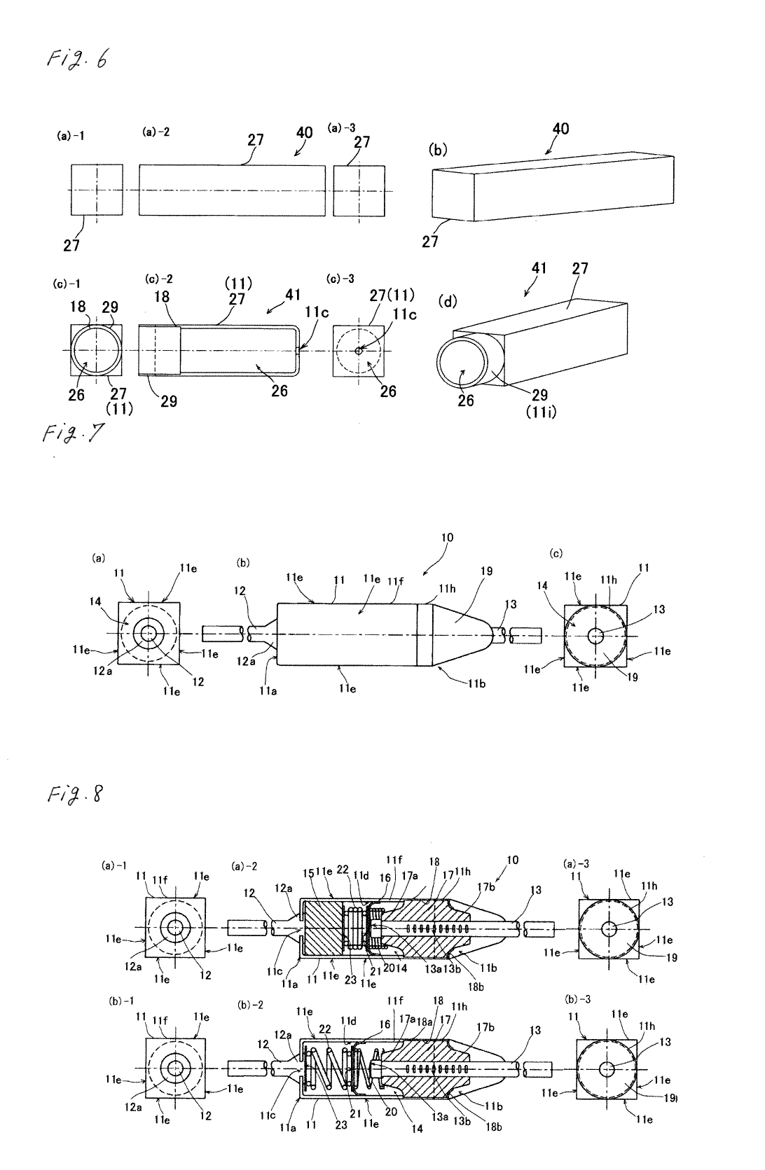

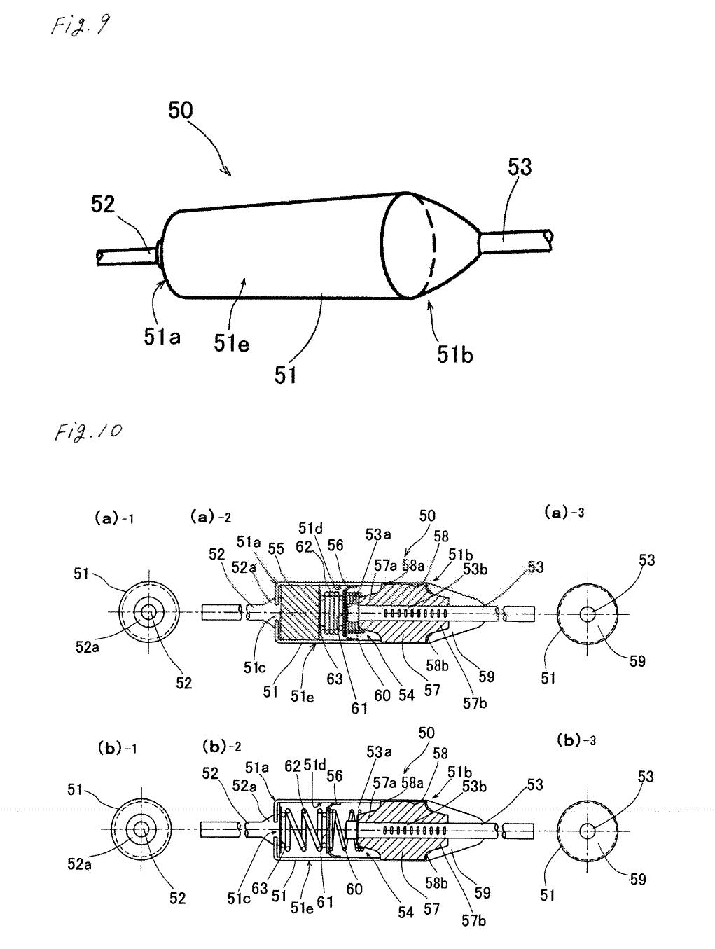

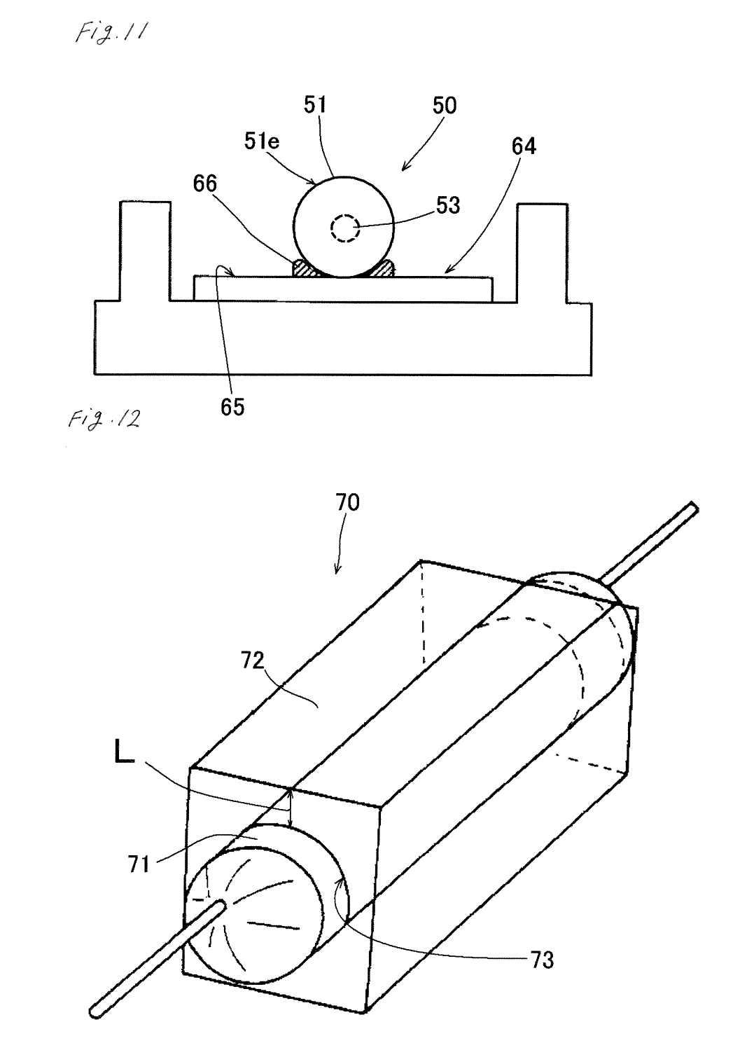

Further, FIG. 2 shows the temperature-sensitive pellet type thermal fuse 10 according to this embodiment, wherein FIG. 2(a)-1 is a front view of the temperature-sensitive pellet type thermal fuse 10 in a conductive state, FIG. 2(a)-2 is a longitudinal cross-sectional view of the temperature-sensitive pellet type thermal fuse 10 in a conducive state, FIG. 2(a)-3 is a rear view of the temperature-sensitive pellet type thermal fuse 10 in a conductive state, FIG. 2(b)-1 is a front view of the temperature-sensitive pellet type thermal fuse 10 in a cut-off state, FIG. 2(b)-2 is a longitudinal cross-sectional view of the temperature-sensitive pellet type thermal fuse 10 in a cut-off state, and FIG. 2(b)-3 is a rear view of the temperature-sensitive pellet type thermal fuse 10 in a cut-off state.

As shown in FIG. 2(a)-1 to FIG. 2(a)-3, the above-mentioned four-sided cylindrical case 11 has the hollow portion 14 in the inside thereof, and a caulking hole portion 11c for fixing a rear end portion 12a of the above-mentioned first lead line 12 is formed in one end portion 11a of the four-sided cylindrical case 11.

Further, in the hollow portion 14, a solid columnar molten pellet 15 which is melted at a predetermined temperature, a first pushing plate 23 which has one surface portion thereof brought into contact with the molten pellet 15, a first coil spring 22 which has one end portion thereof brought into contact with the other surface portion of the first pushing plate 23, a second pushing plate 21 which has one surface portion thereof brought into contact with the other end portion of the first coil spring 22, and a movable contact 16 which has one surface portion thereof brought into contact with the other surface portion of the second pushing plate 21 are arranged.

Further, a rear end portion 13a of the second lead line 13 is arranged at an approximately longitudinal center portion of the hollow portion 14 of the four-sided cylindrical case 11 in a state where the rear end portion 13a is brought into contact with the other surface portion of the movable contact 16.

Further, with respect to the second lead line 13, an outer peripheral portion of a portion 13b which is arranged inside the four-sided cylindrical case 11 is formed into a substantially circular cylindrical shape as a whole, and a ceramic-made bushing 17 which has projecting portions 17a, 17b on both longitudinal end portions thereof is arranged on the outer peripheral portion of the portion 13b.

Further, on a portion of the four-sided cylindrical case 11 ranging from the substantially longitudinal center portion of an inner peripheral surface portion 11d to the other end portion 11b, the bushing fixing stepped portion 18 is formed, and an outer peripheral surface portion of the bushing 17 is fitted in the bushing fixing stepped portion 18.

Further, the bushing 17 is formed into a substantially circular cylindrical shape as a whole, and includes the projecting portions 17a, 17b on both longitudinal end portions of the bushing 17. A proximal end portion of the projecting portion 17a is engaged with one end portion 18a of the bushing fixing stepped portion 18 and, at the same time, a peripheral portion of the projecting portion 17b is fixed to the bushing fixing stepped portion 18 by a the-other-end portion 18b of the bushing fixing stepped portion 18 by caulking.

Further, to the other longitudinal end portion 11b of the four-sided cylindrical case 11, a fitting member 19 which is made of an epoxy resin and is formed into a substantially frustoconical shape is provided. The second lead line 13 is arranged such that the second lead line 13 penetrates the bushing 17 and the fitting member 19 and projects in the longitudinal outward direction of the four-sided cylindrical case 11 from the other longitudinal end portion 11b of the four-sided cylindrical case 11.

Further, the movable contact 16 is formed of a metal-made disc having an outer peripheral portion thereof bent along the longitudinal direction of the four-sided cylindrical case 11, the movable contact 16 is arranged in a state where the movable contact 16 is brought into contact with the above-mentioned rear end portion 13a of the second lead line 13 and, at the same time, the outer peripheral portion of the movable contact 16 is brought into slide contact with the inner peripheral surface portion 11d of the four-sided cylindrical case 11 along the longitudinal direction of the four-sided cylindrical case 11.

Further, the movable contact 16 is biased in the direction that the movable contact 16 moves away from the rear end portion 13a of the second lead line 13 by a second coil spring 20.

Further, the second pushing plate 21 is arranged in a state where the second pushing plate 21 is brought into contact with the movable contact 16. Further, on a side of the second pushing plate 21 opposite to the movable contact 16, the first pushing plate 23 is arranged by way of the first coil spring 22. The first coil spring 22 biases the second pushing plate 21 and the first pushing plate 23 in the direction that the second pushing plate 21 and the first pushing plate 23 move away from each other at a steady temperature state.

In a case shown in FIG. 2(a)-2, an electric current is held in a conductive state by a circuit which is constituted of the first lead line 12, the inner peripheral surface portion 11d of the four-sided cylindrical case 11, the movable contact 16, and the second lead line 13.

The manner of operation of this embodiment is explained in conjunction with drawings hereinafter.

FIG. 4 shows a case where a temperature control target object is the plate-shaped heater portion 24 of the fixing unit of the copying machine printer, and the temperature-sensitive pellet type thermal fuse 10 according to this embodiment is mounted on the rear planar portion 25 of the plate-shaped heater portion 24. FIG. 4(a) is a cross-sectional view showing a mounting state of the temperature-sensitive pellet type thermal fuse 10, and FIG. 4(b) is an enlarged perspective view of a mounting portion of the temperature-sensitive pellet type thermal fuse 10.

As shown in FIG. 4(a), the fixing unit 35 of the copying machine printer according to this embodiment receives a printing paper 38 on which an unfixed toner transferred from a photoconductive drum (not shown in FIG. 4(a) and FIG. 4(b)) is placed on a printing surface side, melts the toner at a high temperature and fixes the toner and, thereafter, conveys and discharges the printing paper 38 therefrom.

Further, to explain the constitution of the fixing unit 35, the fixing unit 35 is constituted of a cylindrical fixing film 36a which is arranged on a printing surface side of the printing paper 38, includes the plate-shaped heater portion 24 such as a ceramic heater in the inside thereof, mounts a polyimide film or a belt on a surface portion thereof and is rotatable in the direction B in the drawing, and a cylindrical pressurizing roller 36b which is arranged on a side of the printing paper 38 opposite to the printing surface, is brought into pressure contact with the fixing film 36a along the longitudinal direction, and is rotatable in the direction B in the drawing.

Further, the printing paper 38 receives a pressure contact force generated between the fixing film 36a and the pressurizing roller 36b while being exposed to a high temperature of approximately 150° C. due to the plate-shaped heater portion 24. Accordingly, a toner which contains styrene acryl or the like as a main component and is melted at the high temperature infiltrates into fibers of the printing paper 38 by melting so that the molten toner is solidified and is fixed.

Further, in the inside of the fixing film 36a, the plate-shaped heater portion 24 having an approximately rectangular plate shape, and a stay portion 37 which is arranged on an upper surface portion of the plate-shaped heater portion and is formed into an approximately U shape in the longitudinal cross section are disposed.

Further, on the substantially longitudinal center portion of the stay portion 37, a four-sided cylindrical case fixing hole portion 37a having an approximately rectangular shape is arranged, wherein the four-sided cylindrical case fixing hole portion 37a has the substantially same widthwise size as the four-sided cylindrical case 11. The four-sided cylindrical case 11 is fitted in the four-sided cylindrical case fixing hole portion 37a and, at the same time, the rear planar portion 25 of the plate-shaped heater portion 24 and the planar portion 11e of the four-sided cylindrical case 11 are arranged to be in contact with each other.

Further, the four-sided cylindrical case 11 is biased by a pressurizing spring 34 which is a coil spring from above such that the four-sided cylindrical case 11 is always brought into close contact with the rear planar portion 25 of the plate-shaped heater portion 24.

Since the rear planar portion 25 of the plate-shaped heater portion 24 and the four-sided cylindrical case 11 are brought into face contact with each other in this manner, different form a line contact which is adopted by the conventional a cylindrical case, heat generated from the plate-shaped heater portion 24 is transferred to the four-sided cylindrical case 11 by way of the whole contact surface and hence, the heat is rapidly transferred to the whole four-sided cylindrical case 11. As shown in FIG. 2(b)-2, at a stage where a temperature of the four-sided cylindrical case 11 arrives at a predetermined temperature (228° C. in this embodiment), the molten pellet 15 shown in FIG. 2(a)-2 is melted so that, as shown in FIG. 2(b)-2, the second coil spring 20 and the first coil spring 22 extend whereby the movable contact 16 slides in the inside of the four-sided cylindrical case 11 in the direction that the movable contact 16 moves away from the rear end portion 13a of the second lead line 13 due to the biasing force of the second coil spring 20.

Due to such an operation, a contact between the movable contact 16 and the rear end portion 13a of the second lead line 13 is released and hence, a circuit leading to the second lead line 13 from the movable contact 16 is cut off whereby the supply of electricity to the plate-shaped heater portion 24 is stopped. Accordingly, the temperature elevation of the heater is stopped thus preventing the ignition of the plate-shaped heater portion 24 caused by abnormal heating.

Further, the four-sided cylindrical case 11 receives heat through the whole planar portion lie and hence, it is possible to obtain not only an advantageous effect that heat response speed or ability is enhanced but also an advantageous effect that the molten pellet 15 which is sealed in the inside of the four-sided cylindrical case 11 is melted uniformly in a short time. Accordingly, it is possible to provide the temperature-sensitive pellet type thermal fuse 10 which hardly generates a defective cut-off or the like and can ensure high operational reliability.

Particularly, recently, there has been developed a fixing unit of a type in which generated heat is transferred to a thin base member which is arranged on a surface of the fixing film 36a by way of a polyimide film or belt having extremely small specific heat capacity compared to an aluminum member or the like. Therefore, a time necessary for obtaining a temperature necessary for fixing toner is sharply shortened thus shortening a warm-up time and reducing the power consumption.

To be more specific, also with respect to a heater which is mounted in the fixing film 36a, by exchanging a halogen lamp (850 W) with a ceramic heater (plate-shaped heater portion 24; 500 W), it is possible to largely reduce the power consumption.

Further, a warm-up time can be shortened from 18 seconds to 0 second by adopting the fixing film 36a. Further, the power consumption at the time of copying one sheet of paper is decreased by half or more, that is, from 5.2 Wh to 2.2 Wh.

By mounting the temperature-sensitive pellet type thermal fuse 10 of the present invention which has the planar portion on the above-mentioned fixing unit 35, the temperature-sensitive pellet type thermal fuse 10 can instantaneously detect the abnormal temperature elevation and cut off the heater circuit. Accordingly, the whole power consumption can be largely decreased thus making the large contribution as an energy saving technique or an environment compatible technique.

The temperature-sensitive pellet type thermal fuse 10 according to this embodiment exhibits the excellent responsiveness as described above and hence, the temperature-sensitive pellet type thermal fuse 10 can rapidly respond to the above-mentioned sharp temperature elevation.

The conventional circular cylindrical temperature-sensitive pellet type thermal fuse cannot perform the above-mentioned biasing using the spring and hence, the fuse has a drawback that the cylindrical case is floated from the heater portion or the like. This embodiment can prevent the occurrence of such a phenomenon.

Further, expensive heat-conductive silicon grease which is necessary for enhancing the heat conductivity in the conventional circular cylindrical thermal fuse is unnecessary in this embodiment and hence, this embodiment can largely reduce a cost of a silicon grease material and a cost for installation such as applying of the grease or a fuse mounting state inspection.

A result of measurement of heat responsiveness under the same condition is described hereinafter with respect to the temperature-sensitive pellet type thermal fuse 10 according to this embodiment, the conventional cylindrical temperature-sensitive pellet type thermal fuse 50 and the thermal fuse 70 according to patent document 1.

### [Sample Served for Test]

(1) Temperature-Sensitive Pellet Type Thermal Fuse According to this Embodiment

Length of heat sensitive surface (planar portion): 8 mm

Length of elongated case: 10 mm

Width of heat sensitive surface: 4 mm

Operation temperature: 228° C.

### (2) Conventional Temperature-Sensitive Pellet Type Thermal Fuse

Length of elongated case: 10 mm

Diameter of elongated case: 4 mm

Operation temperature: 228° C.

### (3) Thermal Fuse Described in Patent Document 1

Length of rectangular parallelepiped heat absorbing fin: 10 mm

Width of rectangular parallelepiped heat absorbing fin: 7 mm

Material of fin: brass (same material as elongated case)

Cylindrical fuse inserted into the fin: same specification as (2)

Operation temperature: 228° C.

### [Mounting Condition]

(1) Temperature-Sensitive Pellet Type Thermal Fuse According to this Embodiment

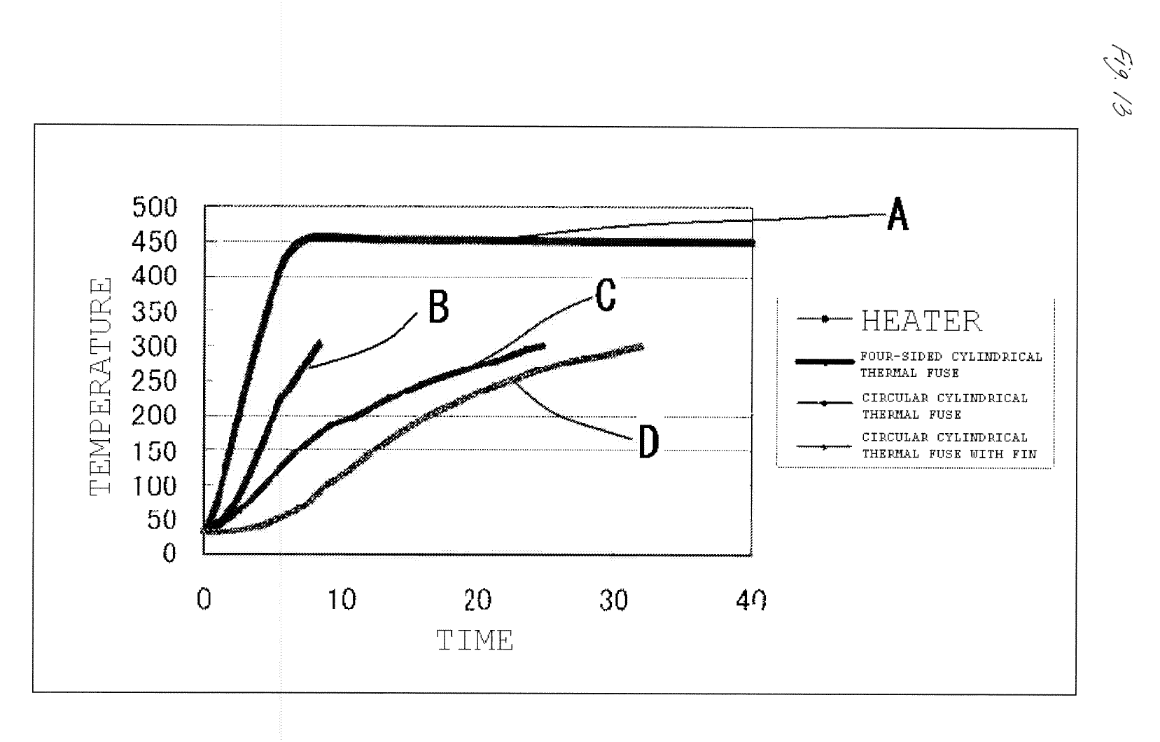

As shown in FIG. 11, the temperature-sensitive pellet type thermal fuse is mounted on the planar portion 65 of the temperature control target object 64 by bringing the planar portion 11e (not shown in FIG. 11) into contact with the planar portion 65 with a load.

However, heat conductive grease 66 shown in FIG. 11 is not used.

### (2) Conventional Circular Cylindrical Temperature-Sensitive Pellet Type Thermal Fuse

As shown in FIG. 11, the temperature-sensitive pellet type thermal fuse is mounted on the planar portion 65 of the temperature control target object 64 by bringing the outer peripheral surface portion 51e of the circular cylindrical case into contact with the planar portion 65 with a load.

However, heat conductive grease 66 shown in FIG. 11 is not used.

### (3) Thermal Fuse Described in Patent Document 1

As shown in FIG. 11, the thermal fuse is mounted on the planar portion 65 of the temperature control target object 64 by bringing the heat absorbing fin 72 (not shown in FIG. 11) into contact with the planar portion 65 with a load.

However, heat conductive grease 66 shown in FIG. 11 is not used.

### [Measuring Condition]

Time which elapses until the thermal fuse is operated (heat response time) is measured under conditions where a temperature of the planar portion of the temperature control target object is elevated to 30° C. to 450° C., and a point of time that the temperature elevation starts is set as 0 second.

Time which elapses until the temperature of the planar portion is elevated to 450° C. is approximately 7 seconds.

### [Result of Measurement]

The result of measurement of heat response time with respect to the above-mentioned respective samples is shown in Table 1. Further, a change in temperature of the respective samples with time is shown in FIG. 13.

TABLE 1

| | | | circular |
|---|---|---|---|
| | | | cylindrical |
| | four-sided | circular | thermal fuse |
| | cylindrical | cylindrical | with heat |
| sample | thermal fuse | thermal fuse | absorbing fin |
| operation temperature | 5.6 | 14.2 | 19.4 |
| (228° C.) arrival time | | | |
| (second) | | | |
| difference in heat | 1 | slower by 2.54 | slower by 3.46 |
| responsiveness | | times | times |
| (assuming heat | | | |
| responsiveness of | | | |
| four-sided cylindrical | | | |
| thermal fuse as 1) | | | |
| (times) | | | |
| difference in heat | faster by 2.54 | 1 | slower by 1.37 |
| responsiveness | times | | times |
| (assuming heat | | | |
| responsiveness of | | | |
| circular cylindrical | | | |
| thermal fuse as 1) | | | |
| (times) | | | |

As shown in Table 1, in the temperature-sensitive pellet type thermal fuse according to this embodiment, the heat response time from a point of time that the temperature elevation starts to a point of time that the thermal fuse is operated is 5.6 seconds.

On the other hand, the heat response time of the conventional circular cylindrical thermal fuse is 14.2 seconds (2.54 times as large as heat response time of this embodiment), and the heat response time of the thermal fuse according to patent document 1 is 19.4 seconds (3.46 times as large as heat response time of this embodiment). Accordingly, the remarkable enhancement of heat responsive time performance is recognized with respect to the thermal fuse having the constitution according to this embodiment.

Further, as shown in FIG. 13, although the temperature of the temperature-sensitive pellet type thermal fuse according to this embodiment is elevated approximately in accordance with a temperature elevation curve A of a heater (curve B), the inclination of a temperature elevation curve is gentle with respect to the conventional circular cylindrical fuse and the thermal fuse according to patent document 1 (curve C and curve D). This result shows that the conventional cylindrical thermal fuse and the thermal fuse according to patent document 1 cannot follow the temperature elevation of the heater.

From above, it is clearly understood that the temperature-sensitive pellet type thermal fuse 10 according to this embodiment can realize the large enhancement of heat responsiveness compared to the heat responsiveness of the conventional circular cylindrical fuse and the thermal fuse described in patent document 1.

A manufacturing method of the four-sided cylindrical case 11 of the temperature-sensitive pellet type thermal fuse 10 according to this embodiment is explained in conjunction with attached drawings.

FIG. 5 shows one example of manufacturing steps of the elongated case of the temperature-sensitive pellet type thermal fuse 10 according to this embodiment, wherein FIG. 5(a)-1 is a front view of the four-sided cylindrical case base member 27 in step 30, FIG. 5(a)-2 is a longitudinal cross-sectional view of the four-sided cylindrical case base member 27, FIG. 5(a)-3 is a rear view of the four-sided cylindrical case base member 27, FIG. 5(b) is a perspective view of the four-sided cylindrical case base member 27 in the same step 30, FIG. 5(c)-1 is a front view of the four-sided cylindrical case base member 27 in step 31, FIG. 5(c)-2 is a longitudinal cross-sectional view of the four-sided cylindrical case base member 27, FIG. 5(c)-3 is a rear view of the four-sided cylindrical case base member 27, FIG. 5(d) is a perspective view of the four-sided cylindrical case base member 27 in step 31, FIG. 5(e)-1 is a front view of the four-sided cylindrical case base member 27 in step 32, FIG. 5(e)-2 is a longitudinal cross-sectional view of the four-sided cylindrical case base member 27, FIG. 5(e)-3 is a rear view of the four-sided cylindrical case base member 27, FIG. 5(f) is a front view of the four-sided cylindrical case base member 27 (four-sided cylindrical case 11) in step 33, FIG. 5(f)-2 is a longitudinal cross-sectional view of the four-sided cylindrical case base member 27, and FIG. 5(f)-3 is a rear view of the four-sided cylindrical case base member 27.

The four-sided cylindrical case 11 of the temperature-sensitive pellet type thermal fuse 10 according to this embodiment is manufactured by: a step 30 of forming a metal base member having a four-sided cylindrical profile as a whole and having a circular cylindrical hollow portion 26 which includes an opening portion on both end portions thereof along the longitudinal direction of the four-sided cylinder as an integral body by drawing using a mold, and forming a four-sided cylindrical case base member 27 having an opening portion on both longitudinal end portions thereof by cutting the metal base member into a predetermined size as shown in FIG. 5(a) and FIG. 5(b); a step 31 of forming a pair of short circular cylindrical portions 28, 29 which projects outward in the longitudinal direction, has an opening portion on both longitudinal end portions of the four-sided cylindrical case base member 27, and has the same inner diameter as the circular cylindrical hollow portion 26 at both longitudinal end portions of the four-sided cylindrical case base member 27 by cutting as shown in FIG. 5(c) and FIG. 5(d); a step 32 of forming the caulking hole portion 11c by gradually narrowing a diameter of the opening portion of the short circular cylindrical portions 28 by drawing and forging as shown in FIG. 5(e), and a step 33 of forming the bushing fixing stepped portion 18 by cutting on an inner peripheral surface portion of the circular cylindrical hollow portion 26 on the other-end-portion side in the longitudinal direction extending over a predetermined length as shown in FIG. 5(f).

By carrying out the above-mentioned steps, it is possible to form the four-sided cylindrical case 11 having a four-sided cylindrical shape using a single member so that it is possible to easily form the elongated case having the same appearance as the thermal fuse 70 according to patent document 1 and having more excellent heat responsiveness than the thermal fuse 70 according to patent document 1. Further, it is possible to form the four-sided cylindrical case base member 27 having a four-sided cylindrical profile and the circular cylindrical hollow portion 26 by drawing and a cutting operation and hence, the number of cutting steps which require the large number of forming man-hours can be decreased as much as possible thus realizing the reduction of a manufacturing cost.

### Embodiment 2

Further, FIG. 6 shows another example of manufacturing steps of the four-sided cylindrical case of the temperature-sensitive pellet type thermal fuse 10 according to this embodiment, wherein FIG. 6(a)-1 is a front view of the four-sided cylindrical case base member 27 in step 40, FIG. 6(a)-2 is a side view of the four-sided cylindrical case base member 27, FIG. 6(a)-3 is a rear view of the four-sided cylindrical case base member 27, FIG. 6(b) is a perspective view of the four-sided cylindrical case base member 27 in the same step 40, FIG. 6(c)-1 is a front view of the four-sided cylindrical case base member 27 in step 41, FIG. 6(c)-2 is a longitudinal cross-sectional view of the four-sided cylindrical case base member 27, FIG. 6(c)-3 is a rear view of the four-sided cylindrical case base member 27 in step 41, and FIG. 6(d) is a perspective view of the four-sided cylindrical case base member 27 in step 41.

The four-sided cylindrical case 11 of the temperature-sensitive pellet type thermal fuse 10 according to this embodiment can be also manufactured by: a step 40 of forming the four-sided cylindrical case base member 27 by cutting a metal base member formed in a four-sided cylindrical shape by drawing into a predetermined length as shown in FIG. 6(a) and FIG. 6(b); and a step 41 of forming a circular cylindrical hollow portion 26 in the four-sided cylindrical case base member 27 by cutting; forming a caulking hole portion 11c in one end portion of the four-sided cylindrical case base member 27, forming a short circular cylindrical portion 29 which projects outward in the longitudinal direction at the other end portion of the four-sided cylindrical case base member 27 by cutting; and forming a bushing fixing stepped portion 18 over a predetermined length on an inner peripheral surface portion of the circular cylindrical hollow portion 26 on the other end portion side in the longitudinal direction by cutting. Also by the manufacturing method of this embodiment, it is possible to form the four-sided cylindrical case 11 having a four-sided cylindrical shape from one material thus easily manufacturing the four-sided cylindrical case of the temperature-sensitive pellet type thermal fuse which exhibits more excellent heat responsiveness than the thermal fuse 70 according to the above-mentioned patent document 1.

FIG. 7(a) to FIG. 7(c) are a front view, an overall side view and a rear view of a temperature-sensitive pellet type thermal fuse 10 which uses the four-sided cylindrical case 11 manufactured by the manufacturing method according to the embodiment 2, FIG. 8(a)-1 to FIG. 8(a)-3 are a front view, a longitudinal cross-sectional view and a rear view of the temperature-sensitive pellet type thermal fuse which uses the four-sided cylindrical case 11 manufactured by the manufacturing method according to the embodiment 2 in a conductive state, and FIG. 8(b)-1 to FIG. 8(b)-3 are a front view, a longitudinal cross-sectional view and a rear view of the temperature-sensitive pellet type thermal fuse 10 which uses the four-sided cylindrical case 11 manufactured by the manufacturing method according to the embodiment 2 in a cut-off state.

As shown in FIG. 7 and FIG. 8, the temperature-sensitive pellet type thermal fuse 10 which uses the four-sided cylindrical case 11 manufactured by the manufacturing method of the embodiment 2 also does not differ in constitution from the temperature-sensitive pellet type thermal fuse 10 according to the embodiment 1 except for a point that the short circular cylindrical projecting portion 11h is provided to only the other longitudinal end portion 11b side of the four-sided cylindrical case 11. Further, the internal structure of the four-sided cylindrical case 11 is substantially equal to the internal structure of the four-sided cylindrical case 11 of the embodiment 1 and hence, the temperature-sensitive pellet type thermal fuse 10 according to the embodiment 2 can acquire the same manner of operation and advantageous effects as the temperature-sensitive pellet type thermal fuse 10 according to the embodiment 1.

With respect to the internal structure of the four-sided cylindrical case of the temperature-sensitive pellet type thermal fuse described in the embodiments 1 and 2, even when the internal constitution of the four-sided cylindrical case is suitably modified, the modification can acquire the substantially equal manner of operation and advantageous effects as these embodiments provided that the shape of the four-sided cylindrical case is equal.

Further, the length and the width of the four-sided cylindrical case can be also suitably modified depending on a kind of the temperature control target object to be mounted or the like.

### INDUSTRIAL APPLICABILITY

The present invention is applicable to the improvement of a temperature-sensitive pellet type thermal fuse which detects a temperature of a temperature control target object, and a manufacturing method of the temperature-sensitive pellet type thermal fuse.

### DESCRIPTION OF THE REFERENCE NUMERALS AND SIGNS

10: temperature-sensitive pellet type thermal fuse
11: four-sided cylindrical case
11a: one longitudinal end portion of four-sided cylindrical case
11b: the other longitudinal end portion of four-sided cylindrical case
11c: caulking hole portion
11d: inner peripheral surface portion of four-sided cylindrical case
11e: planar portion of four-sided cylindrical case
11f: four-sided-cylindrical-case body portion
11g: projecting portion of four-sided cylindrical case
11h: projecting portion of four-sided cylindrical case
12: first lead line
12a: rear end portion of first lead line
13: second lead line
13a: rear end portion of second lead line
13b: portion of second lead line arranged inside four-sided cylindrical case
14: hollow portion of four-sided cylindrical case
15: molten pellet
16: movable contact
17: bushing
17a: projecting portion of bushing
17b: projecting portion of bushing
18: bushing fixing stepped portion
18a: one end portion of bushing fixing stepped portion
18b: the other end portion of bushing fixing stepped portion
19: fitting member
20: second coil spring
21: second pushing plate
22: first coil spring
23: first pushing plate
24: heater portion (temperature control target object)
25: rear planar portion of heater portion (temperature control target object)
26: circular cylindrical hollow portion of four-sided cylindrical case base member
27: four-sided cylindrical case base member
28: short circular cylindrical portion of four-sided cylindrical case base member
29: short circular cylindrical portion of four-sided cylindrical case base member
30: manufacturing step of four-sided cylindrical case in embodiment 1
31: manufacturing step of four-sided cylindrical case in embodiment 1
32: manufacturing step of four-sided cylindrical case in embodiment 1
33: manufacturing step of four-sided cylindrical case in embodiment 1
34: fixing-use pressurizing spring
35: fixing unit of copying machine printer
36a: fixing film
36b: pressurizing roller
37: stay portion
37a: fixing hole portion of four-sided cylindrical case
38: printing paper
40: manufacturing step of four-sided cylindrical case in embodiment 2
41: manufacturing step of four-sided cylindrical case in embodiment 2
50: temperature-sensitive pellet type thermal fuse
51: circular cylindrical case
51a: one longitudinal end portion of circular cylindrical case
51b: the other longitudinal end portion of circular cylindrical case
51c: caulking hole portion
51d: inner peripheral surface portion of circular cylindrical case
51e: outer peripheral surface portion of circular cylindrical case
52: first lead line
52a: rear end portion of first lead line
53: second lead line
53a: rear end portion of second lead line
53b: portion of second lead line arranged inside circular cylindrical case
54: hollow portion of circular cylindrical case
55: molten pellet
56: movable contact
57: bushing
57a: projecting portion of bushing
57b: projecting portion of bushing
58: bushing fixing stepped portion
58a: one end portion of bushing fixing stepped portion
58b: the other end portion of bushing fixing stepped portion
59: fitting member
60: second coil spring
61: second pushing plate
62: first coil spring
63: first pushing plate
64: temperature control target object
65: planar portion of temperature control target object
66: heat conductive grease
70: thermal fuse
71: temperature-sensitive pellet type thermal fuse body
72: heat absorbing fin
73: through hole portion

1. A temperature-sensitive pellet type thermal fuse comprising:
an elongated case which has a hollow portion in the inside thereof;
a first lead line which is arranged on one longitudinal end portion side of the elongated case along the longitudinal direction;
a second lead line which is arranged on the other longitudinal end portion side of the elongated case along the longitudinal direction; and
a movable contact which is arranged in the hollow portion and is brought into contact with the second lead line which is always biased in the move-away direction by way of a molten pellet arranged in contact with the first lead line, the movable contact being movable away from the second lead line due to a biasing force when a temperature of a temperature control target object arrives at a predetermined temperature or more and the molten pellet is melted thus cutting off a power source circuit, wherein
the elongated case includes a planar portion which is brought into face contact with a planar portion of the temperature control target object.

2. A temperature-sensitive pellet type thermal fuse according to claim 1, wherein the elongated case is formed into a regular multi-sided cylinder as a whole.

3. A temperature-sensitive pellet type thermal fuse according to claim 2, wherein the elongated case is formed into a regular four-sided cylinder as a whole.

4. A temperature-sensitive pellet type thermal fuse according to claim 1, wherein on the other longitudinal end portion of an inner peripheral surface portion of the elongated case, a bushing fixing stepped portion is formed over a predetermined length.

5. A temperature-sensitive pellet type thermal fuse according to claim 4, wherein in the elongated case, a wall thickness of the planar portion which is brought into contact with the temperature control target object is set to 0.4 mm or less, and a wall thickness of the bushing fixing stepped portion is set to 0.2 mm.

6. A temperature-sensitive pellet type thermal fuse according to claim 1, wherein a surface roughness of the planar portion of the elongated case is set such that the difference between a concave portion and a convex portion of the uneveness is set to 6.3 μm or less.

7. A temperature-sensitive pellet type thermal fuse according to claim 1, wherein an outer surface portion of the elongated case is covered with a silver plating layer.

8. A temperature-sensitive pellet type thermal fuse according to claim 1, wherein the elongated case is made of brass.

9. A manufacturing method of the elongated case of the temperature-sensitive pellet type thermal fuse described in claim 1, the manufacturing method comprising the steps of:
forming a metal base member having a four-sided cylindrical profile as a whole and having a circular cylindrical hollow portion which includes an opening portion on both end portions thereof along a longitudinal direction of the four-sided cylinder as an integral body by drawing using a mold;
forming a four-sided cylindrical case base member having an opening portion on both longitudinal end portions thereof by cutting the metal base member into a predetermined size;
forming a pair of short circular cylindrical portions which projects outward in the longitudinal direction and has the same inner diameter as the circular cylindrical hollow portion which includes the opening portion on both end portions thereof by cutting; and
forming a caulking hole portion by gradually narrowing a diameter of an opening portion of one of the pair of short circular cylindrical portions by drawing and forging.

10. A manufacturing method of the elongated case of the temperature-sensitive pellet type thermal fuse described in claim 1, the manufacturing method comprising the steps of: steps of:
forming a four-sided cylindrical case base member by cutting a metal base member formed in a four-sided cylindrical shape by drawing into a predetermined length:
forming a circular cylindrical hollow portion in the four-sided cylindrical case base member by cutting;
forming a short circular cylindrical portion which projects outward in the longitudinal direction at one end portion of the four-sided cylindrical case base member by cutting; and
forming a caulking hole portion at the other end portion of the four-sided cylindrical case base member by cutting.

11. The manufacturing method of the elongated case of the temperature-sensitive pellet type thermal fuse according to claim 9 or 10, wherein the manufacturing method further includes a step of forming a bushing fixing stepped portion over a predetermined length on an inner peripheral surface portion of the hollow portion on the other longitudinal end portion side by cutting.

12. A mounting method of the temperature-sensitive pellet type thermal fuse described in claim 1, the mounting method comprising the steps of:
bringing a planar portion of the temperature control target object and a planar portion of the elongated case into contact with each other;
arranging a biasing member which biases the elongated case in the direction which brings the elongated case into close contact with the temperature control target object from a side opposite to a contact surface portion of the elongated case; and
fixing the elongated case to the temperature control target object in a close contact state by a biasing force of the biasing member.

13. The mounting method of the temperature-sensitive pellet type thermal fuse according to claim 12, wherein the biasing member is a spring member.

14. The mounting method of the temperature-sensitive pellet type thermal fuse according to claim 12, wherein the temperature control target object is a heating element which is mounted on a fixing unit of a copying machine printer.
